(19) United States
(12) Patent Application Publication
(10) Pub. No.: US 2004/0062135 A1
(43) Pub. Date: Apr. 1, 2004

(54) Semiconductor integrated circuit device and self-test method of memory macro

(75) Inventor: Katsuhiko Itakura, Kasugai (JP)

Correspondence Address: ARENT FOX KINTNER PLOTKIN & KAHN, 1050 CONNECTICUT AVENUE, N.W., SUITE 400, WASHINGTON, DC, 20036, US

(73) Assignee: Fujitsu Limited

(21) Appl. No.: 10/669,427

(22) Filed: Sep. 25, 2003

(30) Foreign Application Priority Data
Sep. 30, 2002 (JP) 2002-284817

(51) Int. Cl. G11C 8/02

(52) U.S. Cl. 365/232

(57) ABSTRACT

A semiconductor integrated circuit device is provided that enables testing of an optimum test unit in a memory macro under optimum test conditions when testing the memory macro provided in the semiconductor integrated circuit device. An inner bus IB is connected to a self-test circuit, and a self-test is performed on each physical region, which is a basic region in a physical address space of a memory cell array 11. The test is performed constantly with a physical region as a basic unit and redundancy remedy of each basic unit can be performed, irrespective of an outer bus OB set in a logical address space under the control of a logical macro. At the time of the self-test, a memory macro 1 can be tested using an internal clock signal iCLK or second-latency-value information L1 that is optimum for the memory macro. Moreover, output latency of the result of detection of a defective memory cell based on the test can be adjusted in accordance with a signal propagation delay time due to a wiring load in the signal route.

### CROSS-REFERENCE TO RELATED APPLICATIONS

This application is based upon and claims the benefit of priority from each of the prior Japanese Patent Application No. 2002-284817 filed on Sep. 30, 2002, the entire contents of which are incorporated herein by reference.

### BACKGROUND OF THE INVENTION

1. Field of the Invention

This invention relates to a semiconductor integrated circuit device having a memory macro and a self-test method of a memory macro. Particularly, it relates to a semiconductor integrated circuit device and a self-test method of a memory macro that enable suitable test on a memory cell array in the memory macro.

2. Description of Related Art

In a semiconductor integrated circuit device, a logical macro and a memory macro are provided in a mixed manner and a circuit operation is thus carried out. The memory macro is generally designed in advance to have optimum operating frequency, optimum data latency and the like in order to realize an optimum access operation in accordance with the process technology by which it is manufactured. On the other hand, the logical macro controls an internal circuit in accordance with the circuit specifications required of the semiconductor integrated circuit device. Therefore, the control of the memory macro in the circuit operation by the semiconductor integrated circuit device is generally performed under operating conditions that are different from the optimum frequency and the optimum data latency for realizing the optimum operation of the memory macro alone.

In a semiconductor memory device disclosed in the Japanese Laid-Open Patent Publication No. 6-45451, its object is to realize a semiconductor memory device that enables easy implementation of a test for specifying a defective part. FIG. 10 shows a circuit block diagram of a self-test circuit. 100 represents a memory. 310 represents a sequence controller, which generates a necessary control signal for the self-test circuit. 320 represents a data generator, which generates data to be rewritten to the memory 100 for a test. 330 represents an address generator, which generates an address signal used in writing data to each memory cell for a test and reading out the written data. 340 represents a data defect judging unit/result storing unit, which receives the data written to each memory cell of the memory from the data generator 320, then compares the written data with the data actually read out from the memory 100, and stores the result of the comparison. When the written data and the read-out data are different from each other, the memory cell is defective and therefore its position is stored. 350 outputs the result of the test stored in the data defect judging unit/result storing unit 340, that is, the position information of the defective part.

In the memory, each memory cell can be accessed by selectively activating a word line and a bit line. A redundancy circuit is generally constructed to replace all the memory cells (bit strings) belonging to one bit line. Therefore, the position information of a defective part is information by bit string.

FIG. 11 shows the difference of redundancy structure due to the difference by logical address space in a memory cell array. In the example shown FIG. 11, the logical structure of address differs with respect to a memory cell array having a physical address space including eight rows (rows 0 to 7) and four columns (columns 0 to 4). (A) shows the case of a logical space including eight rows (rows 0 to VII) and four columns (columns 0 to III). (B) shows the case of a logical space including 16 rows (rows 0 to XV) and two columns (columns 0 and I). Also a redundancy structure (redundancy (1) and redundancy (2)) having a physical structure including eight rows and two columns is provided.

FIG. 11 shows the redundancy structure in the case two defective bits X(1) exist. The column positions of the defective bits X(1) in the physical address space are the 0^{th} column and the first column. Therefore, in the case of (A), the 0^{th} column and the first column as logical columns can be replaced with the redundancies (1) and (2), thus performing redundancy remedy. In the case of (B), the 0^{th} column as a logical column is replaced with the redundancies (1) and (2). That is, in the case of the eight-row four-column logical space ((A) of FIG. 11), the redundancies (1) and (2) are redundancy structures for the separate logical columns, respectively. On the other hand, in the case of the 16-row two-column logical space ((B) of FIG. 11), the two redundancies (1) and (2) collectively become a redundancy structure for the one logical column.

FIG. 12 shows the layout of a memory macro 1 and outer terminals (CLK) and (OUT) of a semiconductor integrated circuit device, on a chip die. In the semiconductor integrated circuit device, not only the memory macro 1 has a storage capacity and a logical address space that differ by circuit specifications, but also a logical macro 2 has a circuit structure and a circuit scale that vary by circuit specifications. Moreover, the semiconductor integrate circuit device must be highly integrated on a predetermined chip die as it needs to be housed in a predetermined package. Generally, the position relation between the memory macro 1 and the logical macro 2 is properly changed in accordance with various circuit structures, circuit scales and allowable chip dies. The layout of the outer terminals including a clock terminal (CLK) and an output terminal (OUT) from the self-test circuit is optimally decided with respect to the logical macro 2. Therefore, in general, the layout of the outer terminals is properly changed by the semiconductor integrated circuit device. Thus, the positional relation between the memory macro 1, the clock terminal (CLK) and the output terminal (OUT) generally varies by the semiconductor integrated circuit device.

In the semiconductor integrated circuit device, an access to the memory macro is performed under operating conditions set by circuit specifications, instead of the optimum frequency and the optimum data latency for realizing the optimum operation of the memory macro alone. Therefore, also in a self-test on the memory macro, the test is performed under these operating conditions set for the semiconductor integrated circuit device. As a test cannot be performed with the optimum frequency and the optimum data latency of the memory macro, there arises a problem that an efficient self-test cannot be carried out.

Specifically, if the operating frequency of the semiconductor integrated circuit device is lower than the optimum frequency, a self-test is carried out at an access speed that does not meet the maximum access speed capability of the memory macro, posing a problem that an unnecessarily long test time might be needed. If the operating frequency of the semiconductor integrated circuit device is higher than the optimum frequency, there also arises a problem that a normal access operation cannot be performed. Moreover, if the data latency in operation of the semiconductor integrated circuit device is smaller than the optimum latency, the time for data input/output from the memory cell array cannot be secured, posing a problem that correct data input/output might not be carried out. If the data latency in operation of the semiconductor integrated circuit device is larger than the optimum latency, an unnecessarily long time is secured when inputting/outputting data, posing a problem that an unnecessarily long test time is needed.

By properly setting a logical address space for each semiconductor integrated circuit device with respect to a memory cell array having a predetermined physical address space, as shown in FIG. 11, it is possible to set a memory macro having various logical address spaces. However, since the redundancy structure provided thereon is fixed and redundancy remedy is performed for each bit string in the logical space, the total number of bit strings that can be remedied increases or decreases in accordance with the set logical space. The remedy efficiency based on the redundancy structure varies by each logical address space set in the memory macro, posing a problem that the remedy efficiency might be lowered depending on the setting of the logical space.

FIG. 11 shows a specific example. In the case of (A), two defective bits X(2) can be redundancy-remedied by replacing column I and column III as logical columns with the redundancies (1) and (2), respectively. On the other hand, in the case of (B), while defective bits X(2) exist in column 0 and column I as logical columns, the redundancies (1) and (2) collectively form the one-column redundancy structure. Therefore, these defective bits cannot be remedied.

In the example shown in FIG. 11, a bit string is handled as a redundancy remedy unit. Similarly, in the case a word line is used as a redundancy remedy unit, the remedy efficiency based on the redundancy structure varies by each setting of the logical address space, and there arises a problem that the remedy efficiency might be lowered depending on the setting of the logical space.

Moreover, the positional relation between the memory macro and the outer terminals (CLK) and (OUT) to the self-test circuit of the memory macro on the chip die generally changes in accordance with the circuit specifications required of the semiconductor integrated circuit device, as shown in FIG. 12. Therefore, the wiring length for connecting the self-test circuit with the outer terminals (CLK) and (OUT) varies and the wiring load varies accordingly. (A) of FIG. 12 shows the case of a minimum wiring load and a minimum propagation delay time of a signal. (B) shows the case of a large wiring load and a long propagation delay time of a signal. A difference in positional relation on the chip die causes a difference in propagation delay time. Therefore, a problem arises that output timing of an output signal from the outer terminal (OUT) with respect to a clock signal to the outer terminal (CLK) cannot be correctly taken because of the difference in layout position.

### SUMMARY OF THE INVENTION

The present invention has been made to resolve at least one of the above-mentioned problems of the conventional technology. That is, it is an object of the present invention to provide a semiconductor integrated circuit device and self-test method of memory macro, in which memory macros are built, capable of testing the memory macros by optimum number of test units with optimum test condition regardless of operation mode currently set.

To achieve the object, according to one aspect of the present invention, there is provided a semiconductor integrated circuit device provided with a memory macro for conducting access operation to a plurality of memory cells arranged in memory cell array under normal operation by selecting a logical row region and a logical column region that are in a basic region within a logical address space of the memory cell array, the semiconductor integrated circuit device comprising: a defective region detecting section for detecting whether or not a defective memory cell exits by each physical row region or each physical column region based on physical layout of the memory cell array; at least one unit of redundancy region for remedying a defective memory cell by each physical row region or each physical column region in accordance with a detection result obtained by the defective region detecting section; an allocating section for allocating at least one unit of the physical row region or the physical column region to one unit of the logical row region or the logical column region, respectively.

In the semiconductor integrated circuit device directed to one aspect of the present invention, on condition that the allocating section has allocated at least one unit of physical row region or physical column region based on physical layout of the memory cell array to a logical row region or logical column region in logical address space while normal operation, access operation is conducted wherein logical row region or logical column region is dealt as a basic region. On the other hand, the defective region detecting section detects presence/absence of a defective memory cell by each physical row region or each physical column region and depending on detection result, physical row region or physical column region that includes a defective memory cell is remedied using at least one unit of redundancy region by each physical region.

According to the one aspect of the present invention, there is further provided a self-test method of memory macro built in a semiconductor integrated circuit device that includes a memory macro for conducting access operation to a plurality of memory cells arranged in memory cell array under normal operation by selecting a logical row region and a logical column region that are in a basic region within a logical address space of the memory cell array, the self-test method comprising steps of: test-unit extracting step where the logical row region or the logical column region is divided out to at least one unit of physical row region or physical column region, respectively, based on physical layout of the memory cell array; and defective-region extracting step where absence/presence of a defective memory cell is detected for each physical row region or each physical column region.

Thereby, even if access operation is executed to a memory cell array including predetermined physical layout as memory macro based on various logical address space wherein at least one unit of physical row region or physical column region constitute logical row region or logical column region, presence/absence of a defective memory cell can be detected for predetermined physical row region or predetermined physical column region and redundancy remedy can be given to physical row region or physical column region depending on detection result. Redundancy remedy thus can be given to memory macros constituted by various logical row region or logical column region as basic unit by predetermined unit regardless of logical address space layout and stable efficiency of redundancy remedy is secured constantly.

According to second aspect of the present invention, there is provided a semiconductor integrated circuit device provided with a memory macro and a logical macro and operable along with a clock signal supplied from an external section, the semiconductor integrated circuit device comprising: a self-test circuit for conducting a test of the memory macro, the self-test circuit being operable apart from the logical macro and; and a frequency controlling section for converting the clock signal into an internal clock signal that is a maximum frequency of the memory macro when the test of the memory macro is conducted.

In the semiconductor integrated circuit device directed to second aspect of the present invention, the memory macro and logic macro operate in accordance with a clock signal supplied from an external section. Furthermore, the self-test circuit provided for the memory macro includes the frequency controlling section. In the frequency controlling section, a clock signal is converted to an internal clock signal that is maximum frequency of the memory macro and the self-test circuit operates apart from the logical macro to execute memory macro test.

According to the second aspect of the present invention, there is further provided a self-test method of memory macro built in a semiconductor integrated circuit device that includes a memory macro and a logical macro and is operable along with a clock signal supplied from an external section, the self-test method comprising steps of: control stopping step where control of the memory macro by the logical macro is stopped based on a self-test-start command; and test-clock supplying step where the clock signal is converted with reference to the memory macro so that an internal clock signal equivalent to operable frequency of the memory macro is supplied by a self-test-start command.

In the self-test method of memory macro directed to the second aspect of the present invention, control stopping step and test-clock supplying step are executed by a self-test-start command. The control stopping step makes it possible to stop control of the memory macro by the logical macro, and the test-clock supplying step makes it possible to convert a clock signal supplied from an external section into an internal clock signal equivalent to maximum frequency of the memory macro and conduct a memory macro test.

Thereby, even if the semiconductor integrated circuit device is set to operate along with a clock signal of certain operation frequency, which differs from an internal clock signal that has optimum maximum frequency for a memory macro alone, memory macro test by the self-test circuit or a self-test-start command is executed with the clock signal converted to an internal clock signal. Therefore, optimum test is conducted. In other words, self test can be conducted efficiently.

According to third aspect of the present invention, there is provided a semiconductor integrated circuit device provided with a memory macro with self-test function for memory cell array, the semiconductor integrated circuit device comprising: a data-latency controlling section for controlling latency of data inputted/outputted from the memory cell array; a set-latency-value switching section for supplying a first-latency-value information to be set in normal operation and a second-latency-value information to be set in self-test; and a latency-value storing section for storing the second-latency-value information.

In the semiconductor integrated circuit device directed to the third aspect of the present invention, the data-latency controlling section controls latency of data inputted/outputted from the memory cell array. Latency-value information to be controlled are first-latency-value information to be set in normal operation and second-latency-value information to be set in self-test. The set-latency-value switching section supplies the first and second latency value information to the data-latency controlling section. The second-latency-value information is stored in the latency-value storing section.

According to the third aspect of the present invention, there is further provided a self-test method of memory macro built in a semiconductor integrated circuit device provided with a memory macro for conducting data-input/data-output from memory cell array, the self-test method comprising steps of: test-latency-value storing step where test-latency-value information with reference to data inputted/outputted from the memory cell array is stored when self test is conducted; test-latency-value setting step where the test-latency-value information is set in accordance with a self-test-start command; and a data-latency controlling step where latency of data inputted/outputted from the memory cell array is controlled in accordance with the test-latency-value information set in the test-latency value setting step.

In the self-test method of memory macro directed to the third aspect of the present invention, test-latency-value storing step makes it possible to store test-latency-value information with reference to data inputted/outputted from the memory cell array in self-test, test-latency-value setting step makes it possible to set test-latency-value information in accordance with a self-test-start command, and data-latency controlling step makes it possible to control latency of data inputted/outputted from the memory cell array.

Thereby, even if data latency from the memory cell array is controlled and set with the first-latency-value information, which differs from the second-latency-value information or test-latency-value information equivalent to optimum data-latency-value information for a single memory macro alone in normal operation, the data latency is controlled with the second-data-latency-value information or the test-latency-value information during self-test period. Since self-test can be conducted with the second-latency-value information or test-latency-value information that is optimum data-latency-value information for the memory macro, self-test can be conducted under optimum data input/output control. That is, self-test can be conducted efficiently.

According to fourth aspect of the present invention, there is provided a semiconductor integrated circuit device provided with a memory macro with self-test function for memory cell array, the semiconductor integrated circuit device comprising: a defective region storing section for storing a detection result indicating presence/absence of a defective memory cell for each of predetermined regions in the memory cell array; and an output latency controlling section for controlling output latency of the detection result depending on propagation delay time to propagate from the defective region storing section through an output path and operation frequency of the clock signal when the detection result is outputted based on a clock signal supplied from an external section.

In the semiconductor integrated circuit device directed to the fourth aspect of the present invention, when a detection result regarding presence/absence of defective memory cell stored in the defective region storing section is outputted, output latency controlling section controls output latency depending on propagation delay time and operation frequency of a clock signal through an output path from the defective region storing section.

According to the fourth aspect of the present invention, there is further provided A self-test method of memory macro built in a semiconductor integrated circuit device provided with a memory macro for conducting data-input/data-output from memory cell array, the self-test method comprising steps of: defective-region storing step where a detection result of presence/absence of a defective memory cell is stored for each of predetermined regions within the memory cell array; output-latency determining step where an output latency value of the detection result is determined based on propagation delay time until an output of the detection result and operation frequency of the clock signal when the detection result is to be outputted based on a clock signal supplied from an external section; and defective-region outputting step where the detection result is outputted in form of the output latency value based on the clock signal.

In the self-test method of memory macro directed to the fourth aspect of the present invention, output-latency determining step makes it possible to determine an output latency value of the detection result based on propagation delay time until an output of the detection result and operation frequency of the clock signal when a detection result of presence/absence of a defective region stored by the defective-region storing step is outputted based on a clock signal.

Thereby, depending on propagation delay time difference of a detection result caused by positioning difference of the memory macro and an external terminal on a chip-die, timing to output the detection result from the external terminal can be adjusted appropriately based on operation frequency of a clock signal supplied from the external section. Therefore, detection results can be outputted stably regardless of positioning difference of items on a chip-die and frequency differences of a clock signal.

The above and further objects and novel features of the invention will more fully appear from the following detailed description when the same is read in connection with the accompanying drawings. It is to be expressly understood, however, that the drawings are for the purpose of illustration only and are not intended as a definition of the limits of the invention.

### BRIEF DESCRIPTION OF THE DRAWINGS

FIG. 1 is a diagram for explaining the principle of the present invention:

FIG. 2 is a circuit block diagram directed to a first embodiment;

FIG. 3 is a circuit block diagram directed to a second embodiment;

FIG. 4 is a circuit block diagram showing a specific example of frequency controlling section;

FIG. 5 is a circuit block diagram directed to a third embodiment;

FIG. 6 is a circuit diagram showing a specific example directed to the first through third embodiments;

FIG. 7 is a circuit diagram showing a specific example of data-latency controlling section (for one-bit data);

FIG. 8 is an operational waveform diagram of a case that latency 2 is set for the data-latency controlling section in FIG. 7;

FIG. 9 is a circuit block diagram directed to a fourth embodiment;

FIG. 10 is a circuit block diagram of a conventional self-test circuit;

FIG. 11 is a conceptual diagram showing difference of redundancy structure that differs by logical address space in memory cell array; and

FIG. 12 a conceptual diagram showing layout of a memory macro and external terminals of a semiconductor integrated circuit device.

### DETAILED DESCRIPTION OF THE PREFERRED EMBODIMENTS

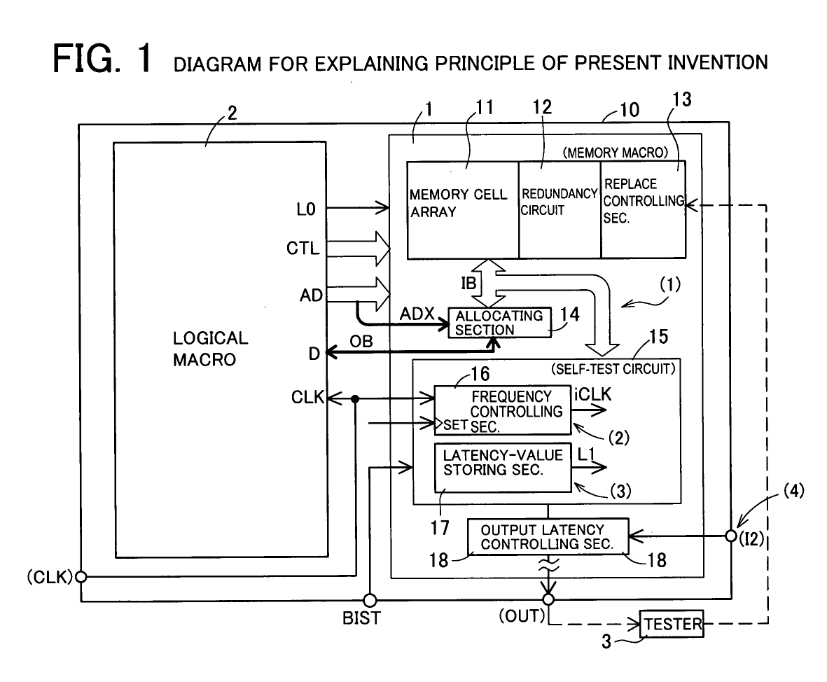

FIG. 1 is a diagram for explaining the principle of the present invention. A semiconductor integrated circuit device 10 has a memory macro 1 and a logical macro 2. In normal use, the logical macro 2 usually controls the memory macro 1. The logical macro 2 supplies various control signals CTL, address signals AD and data-latency-value information L0 to the memory macro 1 and carries out input/output of data D from/to the memory macro 1. A test-start signal BIST of a self-test is supplied to the memory macro 1 from outside. The memory macro 1 and the logical macro 2 operate in accordance with a clock signal CLK supplied via an outer terminal (CLK) from an external device such as a tester 3.

In the memory macro 1, memory cells are arranged in a memory cell array 11 and a redundancy circuit 12. An inner bus IB is connected to the memory cell array 11 for each physical region, which is a basic region in a physical address space, so that data input/output by physical region is performed. The inner bus IB is connected to an allocating section 14 and a self-test circuit 15. The allocating section 14 allocates the inner bus IB for each physical region connected to the memory cell array 11, to an outer bus OB in accordance with a predetermined address ADX of the addresses AD supplied from the logical macro 2. Since at least one inner bus IB is allocated to one outer bus OB, the number of memory cells accessed through one outer bus OB is equal to or larger than the number of memory cells accessed through one inner bus IB. It is controlled by a predetermined address ADX in accordance with the logical address space to the memory cell array 11 set for each design of the semiconductor integrated circuit device 10.

In FIG. 1, a part indicated by (1) is a first principle part of the invention. Since the inner bus IB is connected to the self-test circuit 15, a self-test is performed for each physical region, which is a basic region in the physical address space in the memory cell array 11. The self-test is performed using a physical region based on the physical address space in the memory cell array 11 as a basic unit, irrespective of the logical address space controlled by the logical macro 2. In performing redundancy remedy based on the self-test, a defective memory cell can be remedied at optimum redundancy remedy efficiency.

The self-test circuit 15 is started by the test-start signal BIST. As second and third principle parts of the invention indicated by (2) and (3) in FIG. 1, a frequency controlling section 16 and a latency-value storing section 17 are provided.

A clock signal CLK is inputted to the frequency controlling section 16, which is the second principle part (2) of the invention. Also information related to frequency conversion conditions is inputted to its setting terminal (SET) and an internal clock signal iCLK is outputted from the frequency controlling section 16. The internal clock signal iCLK is used as the operating frequency of the memory macro 1 at the time of the self-test. The information related to frequency conversion conditions inputted to the setting terminal (SET) is directly supplied from outside of the semiconductor integrated circuit device 10, as test condition information. Alternatively, it can be generated within the semiconductor integrated circuit device 10 from the operating frequency of the clock signal CLK. Irrespective of the clock signal CLK supplied from outside, the internal clock signal iCLK can be set at the operating capability frequency in the memory macro 1 at the time of the self-test, and the self-test in the memory macro 1 can be carried out using the optimum operating frequency.

In the latency-value storing section 17, which is the third principle part (3) of the invention, second-latency-value information L1 is stored as the data-latency-value information with respect to the memory cell array 11 at the time of the self-test. The second-latency-value information L1 is supplied to the memory macro 1 in response to the test-start signal BIST. Irrespective of the data-latency-value information L0 set by the logical macro 2 in the normal operation, the self-test can be carried out while controlling data input/output by the second-latency-value information L1, which is the optimum data-latency-value information in the memory macro 1 at the time of the self-test.

When outputting information of the defective memory cell detected for each inner bus IB by the self-test circuit 15 to an external device such as the tester 3, the result of the detection is outputted from an output terminal (OUT) via an output latency controlling section 18 shown in a fourth principle part of the invention indicated by (4) in FIG. 1. The signal route from the self-test circuit 15 in the memory macro 1 to the output terminal (OUT) varies depending on the individual designs of the semiconductor integrated circuit device 10, and in general, the signal propagation delay time varies because of the variance in wiring load. To accurately supply the result of the detection to the tester 3 or the like, test condition information I2 is inputted to the output latency controlling section 18 via an outer terminal (I2) on the basis of the clock signal CLK in accordance with the propagation delay time in the output route. The output latency controlling section 18 sets output-latency-value information L2 based on the test condition information I2. The output-latency-value information L2 can be directly supplied as the test condition information I2, and it can also be internally generated on the basis of the test condition information I2. The result of the detection can be outputted on the basis of the output-latency-value information L2 that matches the operating frequency of the clock signal CLK in each semiconductor integrated circuit device 10.

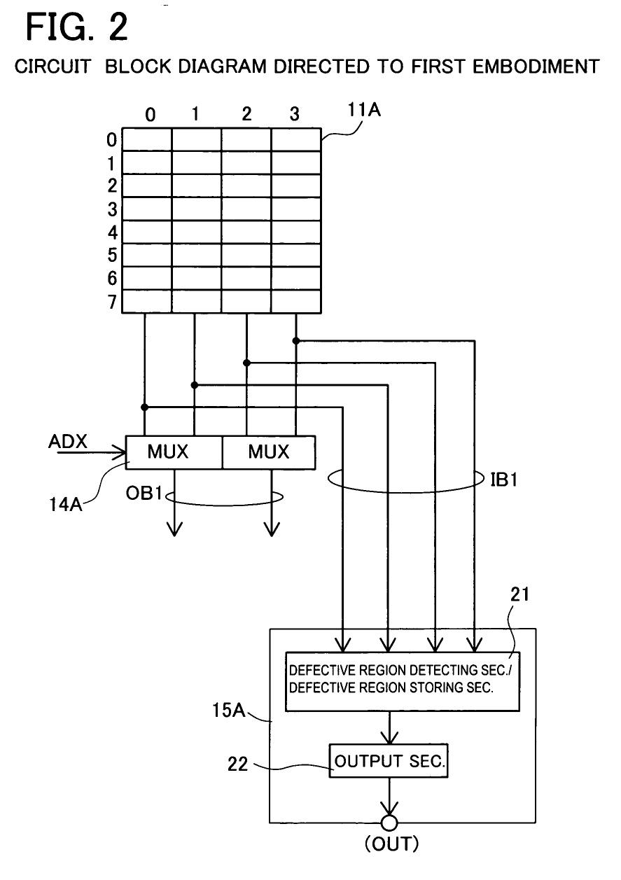

Specific embodiments of the semiconductor integrated circuit device of the present invention will now be described in detail with reference to FIGS. 2 to 9.

FIG. 2 shows an exemplary structure of inner/outer buses from a memory cell array 11A as a first embodiment. The memory cell array 11A has a physical address space including eight rows (rows 0 to 7) and four columns (columns 0 to 4). An inner bus IB1 is provided for each of the physical columns (0 to 4). In the inner bus IB1, one logical column is allocated to two physical columns (columns 0 and 1, columns 2 and 3) by a multiplexer (MUX) 14A. Two logical columns in total are provided as an outer bus OB1. The inner bus IB1 is connected to a self-test circuit 15A. At the time of a self-test, with respect to data of the memory cell array 11A outputted via the inner bus IB1, the presence/absence of a defective memory cell is detected for each physical column by a defective region detecting section 21, and the physical column in which a defective memory cell is detected is stored into a defective region storing section 21. After the self-test, defective position data by physical column stored in the defective region storing section 21 is outputted to an external tester or the like from an output terminal (OUT) via an output section 22. On the basis of the outputted defective position data, redundancy remedy is performed.

In FIG. 2, the relation between the inner bus IB1 and the outer bus OB1 is two-to-one correspondence. That is, one logical column is set to correspond to two physical columns. This allocation can be changed by properly setting the structure of a predetermined address ADX for controlling the allocation at the multiplexer (MUX) 14A, for each design of the semiconductor integrated circuit device. For example, if a one-bit address signal that identifies a physical column is set to be “don't care”, the two-to-one allocation shown in FIG. 2 is given. If a two-bit address signal is set to be “don't care”, one logical column can be allocated to four physical columns. The predetermined address ADX shown in FIG. 2 represents an address bit string except for an address of “don't care”.

In accordance with the logical address space set on the basis of the circuit specifications that should be realized in the semiconductor integrated circuit device, the allocation between the inner bus IB1 and the outer bus OB1 can be suitably changed at the multiplexer (MUX) 14A. Regardless of this change, the inner bus IB1 based on physical columns as basic units is connected with the self-test circuit 15A.

According to the first embodiment, even when an access operation is performed to the memory cell array 11A having a predetermined physical layout as a memory macro while one logical column is constituted by two physical columns on the basis of various logical address spaces, the presence/absence of a defective memory cell can be detected for each physical column and redundancy remedy can be performed in each physical column. To the memory macro 11A having various logical columns as basic units, redundancy remedy by every physical column can be performed irrespective of the logical address space, and a constant redundancy remedy efficiency can be realized.

If the physical columns of this case are set as minimum units that can be electrically controlled, the presence/absence of a defective memory cell can be detected with respect to the minimum units and redundancy remedy can be performed for each minimum unit.

The direction of row is a direction in which a word line for selecting a memory cell is wired. The direction of column is a direction in which a bit line connected with a memory cell is wired. A physical row is a basic unit including a memory cell group selected by a word line that can be electrically controlled independently. A physical column is a basic unit including a memory cell group connected to a bit line that can be electrically controlled independently. As a bit line that can be electrically controlled independently is set as a basic unit, redundancy remedy by minimum unit can be performed. The bit line as a minimum unit is a unit that can be electrically controlled independently, and the number of bit lines can be suitably set in accordance with the design of the memory macro, for example, one bit line or multiple bit lines.

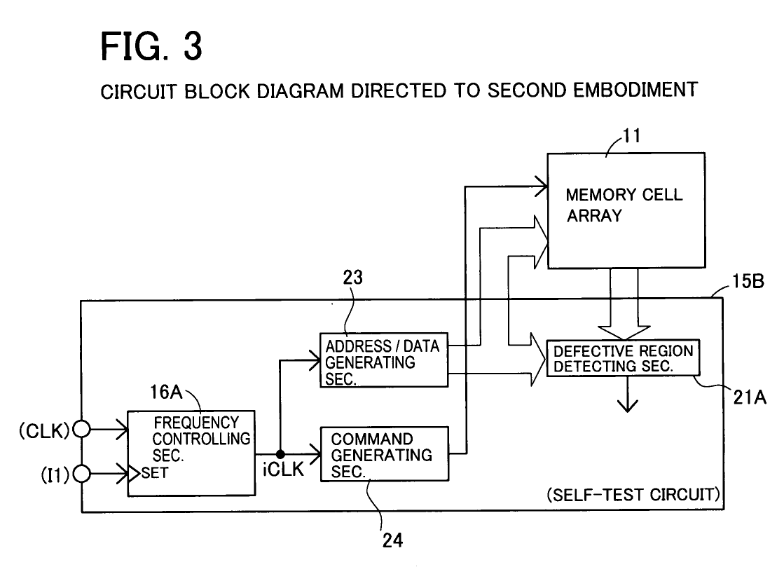

FIG. 3 shows an exemplary structure in the case the operating frequency in a self-test is controlled by a frequency controlling section 16A, as a second embodiment. A self-test circuit 15B has an address/data generating section 23 and a command generating section 24. At the time of a self-test, the self-test circuit 15B supplies address/data and command to a memory cell array 11 and performs input/output of data by every address. In data output, data read out from the memory cell array 11 is outputted to a defective region detecting section 21A. In order to judge the correctness of the read-out data, data from the address/data generating section 23 is inputted to the defective region detecting section 21A. Address information may be inputted together in order to confirm defective data position when defective data is read out.

In the self-test, an internal clock signal iCLK is supplied from the frequency controlling section 16A as a frequency signal prescribing the timing at which address/data and command should be sequentially outputted. To the frequency controlling section 16A, a clock signal CLK supplied from an external tester (not shown) or the like is inputted and test condition information I1 is also inputted. The test condition information I1 is information for deciding a frequency division/multiplication number when generating the internal clock signal iCLK from the clock signal CLK. Since the operating frequency of the internal clock signal iCLK that operates the memory cell array 11 at the maximum speed is known in advance, the frequency division/multiplication number can be decided in accordance with the operating frequency of the clock signal CLK. The test condition information I1 is, for example, a signal obtained by coding the frequency division/multiplication number. Alternatively, the frequency division/multiplication number can be calculated from the clock signal CLK, instead of supplying the test condition information I1.

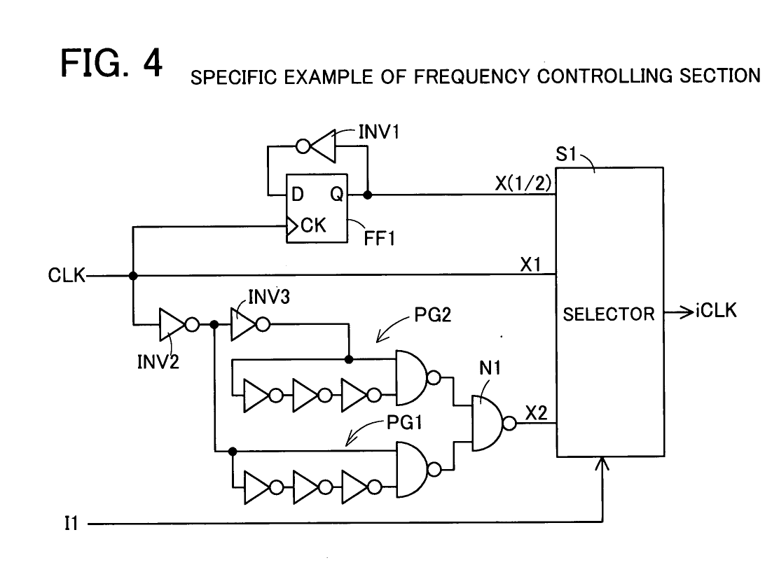

FIG. 4 shows a specific example of the frequency controlling section 16A. FIG. 4 shows the case where frequency conversion is performed on the basis of a signal obtained by coding the frequency division/multiplication number as the test condition information I1. The test condition information I1 controls a selector S1, which selects one of a clock signal CLK(X1), a (½) frequency-divided signal (X(½)) with respect to the clock signal CLK, and a double-frequency signal (X2), and outputs the selected signal as an internal clock signal iCLK.

A circuit that outputs a (½) frequency-divided signal (X(½)) is constituted by a D-flip-flop FF1 and has a structure such that an inverter gate INV1 directed from an output terminal (Q) to an input terminal (D) inverts and inputs an output signal. This circuit structure logically inverts an output signal at each clock signal CLK inputted to a clock terminal (CK), thus generating a (½) frequency-divided signal (X(½)).

A circuit that outputs a double-frequency signal (X2) has two inverter gates INV2, INV3 connected in series, negative pulse generating circuits PG1, PG2 connected with output terminals of the inverter gates INV2, INV3, respectively, and a NAND gate N1 connected with output terminals of the negative pulse generating circuits PG1, PG2. Each of the negative pulse generating circuits PG1, PG2 is a circuit for generating a negative pulse at a rise edge of an input signal, where with respect to an input signal to one input terminal of its two-input NAND gate, a delay signal logically inverted by inverter gates of an odd number of stages (in FIG. 4, three stages are shown) is inputted to its other input terminal. The clock signal CLK is logically inverted by the inverter gates INV2, INV3 and then negative pulse signals are generated by the negative pulse generating circuits PG1, PG2 at rise edges of the respective signals. The negative pulse signals are generated alternately every half cycle of the clock signal CLK. In this case, since the other signal maintains a high level, a double-frequency signal (X2) is outputted at the output terminal of the NAND gate N1 to which these two signals are inputted.

According to the second embodiment, even when the clock signal CLK having an operating frequency different from the operating frequency of the internal clock signal iCLK, which is the optimum operating capability frequency in the memory macro alone, is supplied, the clock signal CLK is converted to the internal clock signal iCLK at the time of the test by the self-test circuit 15B and therefore an optimum test can be carried out. The self-test can be efficiently carried out.

In this case, since the condition of frequency conversion is supplied as the test condition information I1 from the external tester or the like, the frequency controlling section 16A can perform accurate conversion in accordance with the test condition information I1. The test condition information I1 in this case is information related to the frequency division/multiplication number for the clock signal CLK. As the internal clock signal iCLK having the optimum operating capability frequency in the memory macro is known in advance on the stage of designing, the frequency division/multiplication number for the operating frequency in converting the clock signal CLK to the internal clock signal iCLK is decided when the clock signal CLK inputted from outside is decided. The test condition information I1 can be set on the basis of this decided information and accurate conversion can be directly performed. It is also possible to make such setting that the frequency division/multiplication number is calculated from the clock signal CLK.

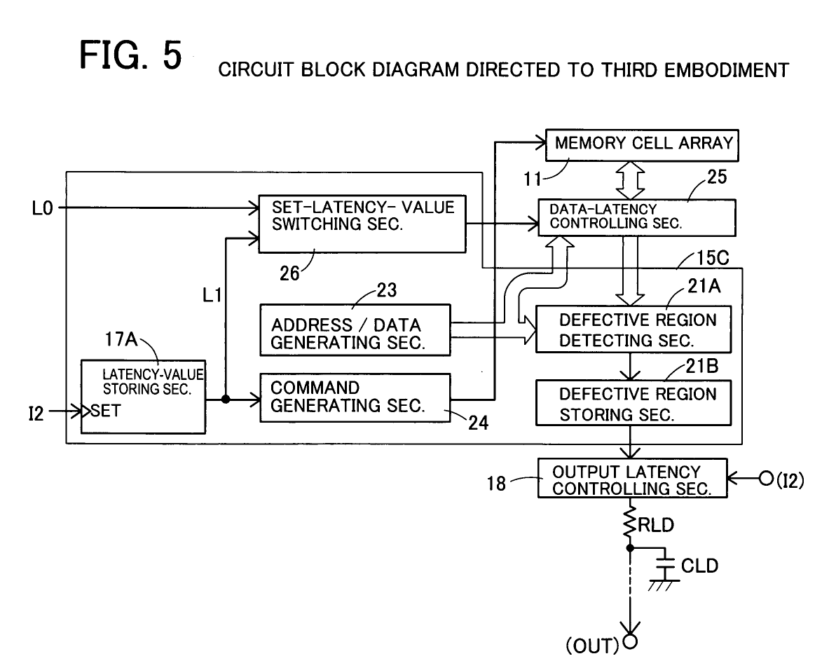

FIG. 5 shows an exemplary structure in the case data latency in data input to/output from a memory cell array 11 at the time of a self-test is controlled by a latency-value storing section 17A, as a third embodiment. A self-test circuit 15C for performing a self-test on the memory cell array 11 is provided.

In the self-test circuit 15C, an address/data generating section 23, a command generating section 24 and a defective region detecting section 21A are the same as those of the second embodiment (FIG. 3). In the third embodiment, the latency-value storing section 17A, a set-latency-value switching section 26, and a data-latency controlling section 25 are provided. In the latency-value storing section 17A, data-latency-value information L1 at the time of the self-test is stored. The data-latency-value information L1 is supplied to the command generating section 24 and also supplied to the set-latency-value switching section 26. To the set-latency-value switching section 26, latency-value information L0 at the time of normal operation and the latency-value information L1 are inputted in a switchable manner. At the time of the test, the latency-value information L1 is selected. The data-latency controlling section 25 performs data-latency control in accordance with the latency-value information selected by the set-latency-value switching section 26. Moreover, a defective region storing section 21B for storing the result of detection by the defective region detecting section 21A, and an output latency controlling section 18 for adjusting output latency when outputting the stored result of detection to outside, are provided. In the signal route from the defective region storing section 21B to an output terminal (OUT), wiring loads RLD, CLD are added in accordance with the layout of the defective region storing section 21B and the output terminal (OUT). To adjust a propagation delay due to these wiring loads, test condition information I2 is inputted to the output latency controlling section 18 from outside. On the basis of the test condition information I2, output latency information L2 is set.

According to the third embodiment, even if the data latency from the memory cell array 11 is controlled with the latency-value information L0 (first latency-value information) at the time of normal operation, the data latency is controlled with the optimum data-latency-value information L1 (second-latency-value information) in the memory macro alone at the time of the self-test. Since the self-test can be performed using the optimum data-latency-value information L1 in the memory macro, the test can be performed using optimum data input/output control. Thus, the self-test can be efficiently performed.

In the self-test, when performing data access using the operating capability frequency in the memory macro, a data latency value that matches the operating capability frequency may be set as the latency-value information L1.

In accordance with the difference in propagation delay time of the result of detection caused by the loads RLD, CLD in the wiring routes due to the difference in layout of the memory macro and the outer terminal (OUT) on a chip die, the output timing of the result of detection outputted from the outer terminal (OUT) can be properly adjusted on the basis of the operating frequency of the clock signal CLK supplied from outside. The result of detection can be stably outputted, irrespective of the difference in layout and the difference in operating frequency of the clock signal CLK.

In this case, since the test condition information I2 is supplied from outside on the basis of the operating frequency of the clock signal in order to adjust the output timing for outputting the result of detection, the output latency controlling section 18 can set accurate output latency information L2 in accordance with the test condition information I2. Since the propagation delay time of the result of detection based on the layout on the chip die is known in advance on the stage of designing, an output latency value that is necessary in the output latency controlling section 18 is decided when the clock signal CLK is decided. On the basis of this decided information, the test condition information I2 can be set and accurate setting can be directly performed.

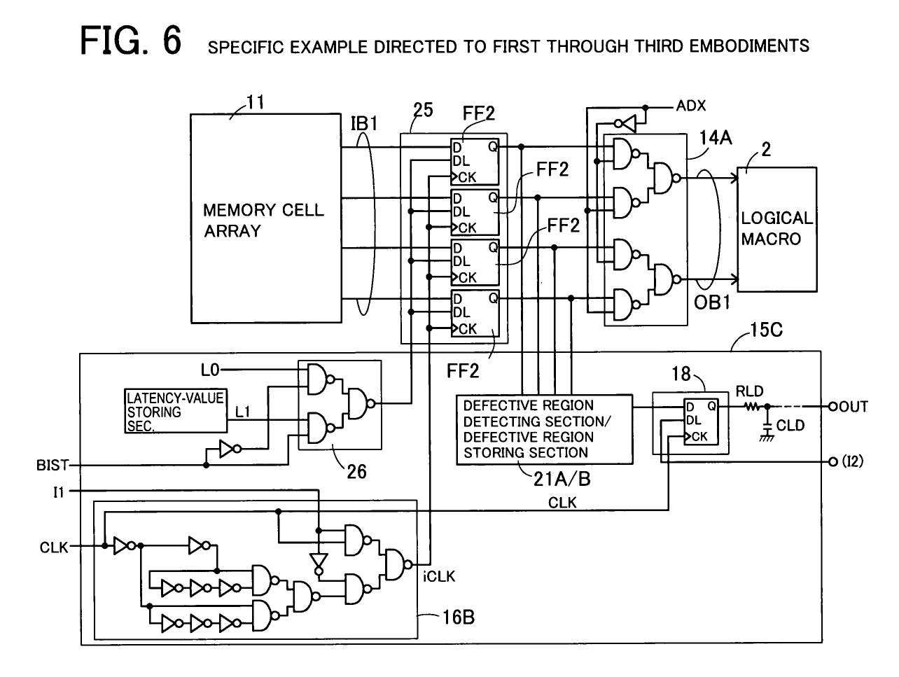

FIG. 6 shows a specific example directed to the first to third embodiments. An inner bus IB1 connected to a memory cell array 11 is inputted to a data-latency controlling section 25 and then allocated to an outer bus OB1 by a multiplexer (MUX) 14A. The multiplexer (MUX) 14A includes two NAND gates to which two adjacent physical columns of the inner bus IB1 and a predetermined address signal ADX, which is a complementary one-bit signal, are combined and inputted, and a NAND gate to which output terminals of the two NAND gates are connected. One of the two physical columns is selected in accordance with the predetermined address signal ADX and data is outputted to one of two logical columns constituting the outer bus OB1.

A frequency controlling section 16B is constructed to select either a clock signal CLK(X1) or a double-frequency signal (X2). A selector has a structure similar to that of the multiplexer (MUX) 14A. A complementary signal is generated with respect to test condition information I1 inputted as a one-bit signal, and this complementary signal is inputted to each NAND gate. One of the NAND gates is selected and an internal clock signal iCLK is selected. The internal clock signal iCLK is inputted to the data-latency controlling section 25.

Also a set-latency-value switching section 26 has a structure similar to that of the multiplexer (MUX) 14A. A complementary signal is generated with respect to a test-start signal BIST and one NAND gate is selected. Latency-value information that should be supplied to the data-latency controlling section 25 is switched. In this case, the switching between latency-value information L0 in a normal operation state and latency-value information L1 at the time of a self-test is outputted as a one-bit signal. It is assumed that the latency-value information L0 and the latency-value information L1 are logical level signals complementary with each other.

The data-latency controlling section 25 includes flip-flops FF2 provided for the physical columns of the inner bus IB1, respectively. The physical columns are connected to input terminals (D) and output terminals (Q). The internal clock signal iCLK is inputted to clock terminals (CK). The latency-value information L0, L1 is inputted to setting terminals (DL).

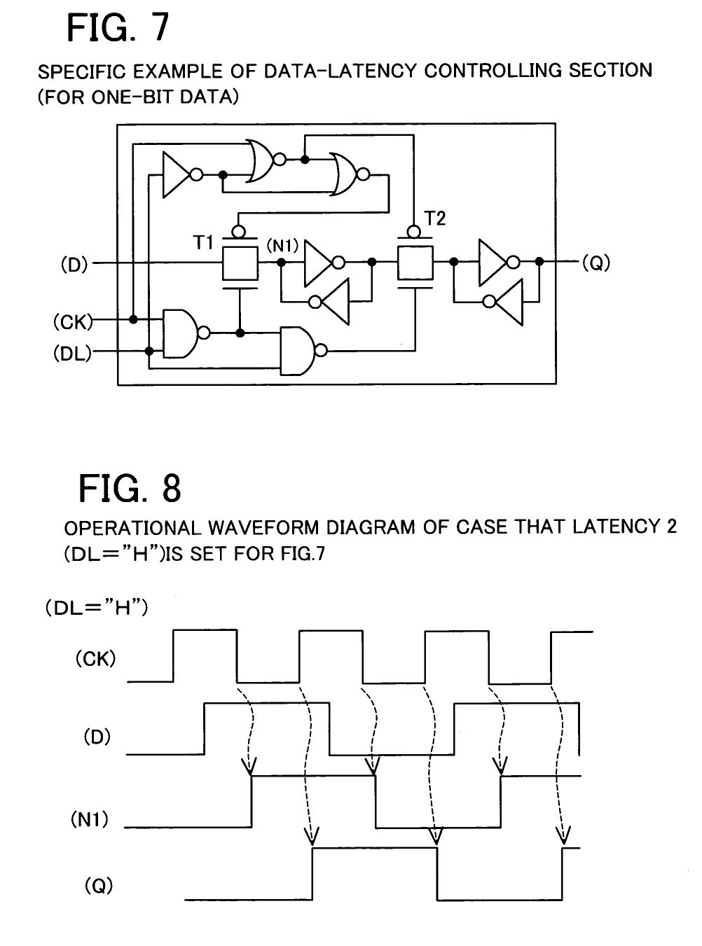

FIG. 7 shows a specific exemplary circuit structure of the flip-flop FF2. In the route from the input terminal (D) to the output terminal (Q), a shift register structure is provided in which transfer gates T1, T2 and a latch circuit including inverter gates are alternately arranged. The transfer gates T1, T2 are controlled in accordance with signals inputted to the clock terminal (CK) and the setting terminal (DL). For the logical levels (0, 0), (0, 1), (1, 0) and (1, 1) of the input signals (CK, DL) inputted to the clock terminal (CK) and the setting terminal (DL), the conducting state (Ti, T2) of the transfer gates T1, T2 is (T1, T2)=(ON, ON), (ON, OFF), (ON, ON) and (OFF, ON). Therefore, if the input signal inputted to the setting terminal (DL) is at a low level, both the transfer gates T1, T2 are constantly in the ON-state. The latency value in this case is 1. If the input signal inputted to the setting terminal (DL) is at a high-level, the transfer gate T1 is turned on when a low-level signal is inputted to the clock terminal (CK), and data at the input terminal (D) is taken in and latched at a node N1. The transfer gate T2 is turned on when a high-level signal is inputted to the clock terminal (CK), and the data latched at the node N1 is outputted to the output terminal (Q). The latency value in this case is 2.

FIG. 8 shows an operational waveform in the case a high-level signal is inputted to the setting terminal (DL) as latency-value information. It is an operational waveform in the case the latency value is 2. In accordance with low-level transition of the clock signal to the clock terminal (CK), high-level data inputted to the input terminal (D) is taken in and latched at the node N1. When the clock signal shifts to a high level, the data at the node N1 is outputted from the output terminal (Q).

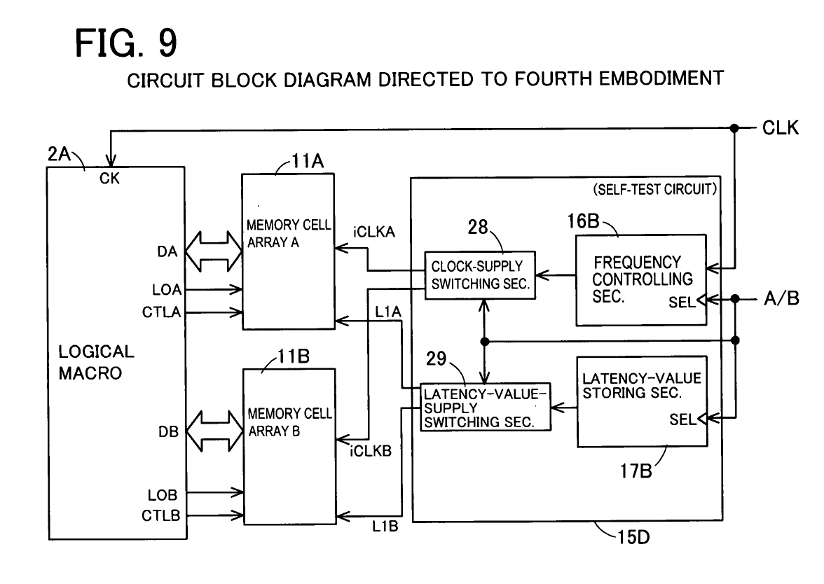

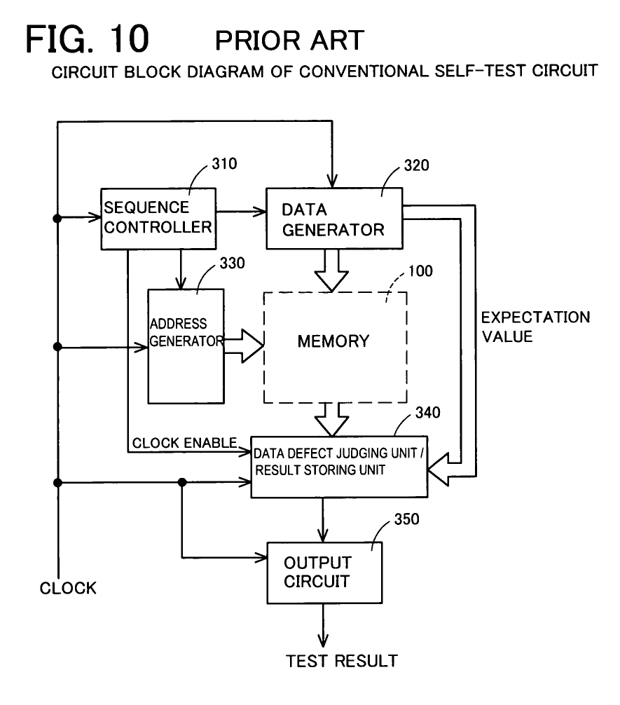

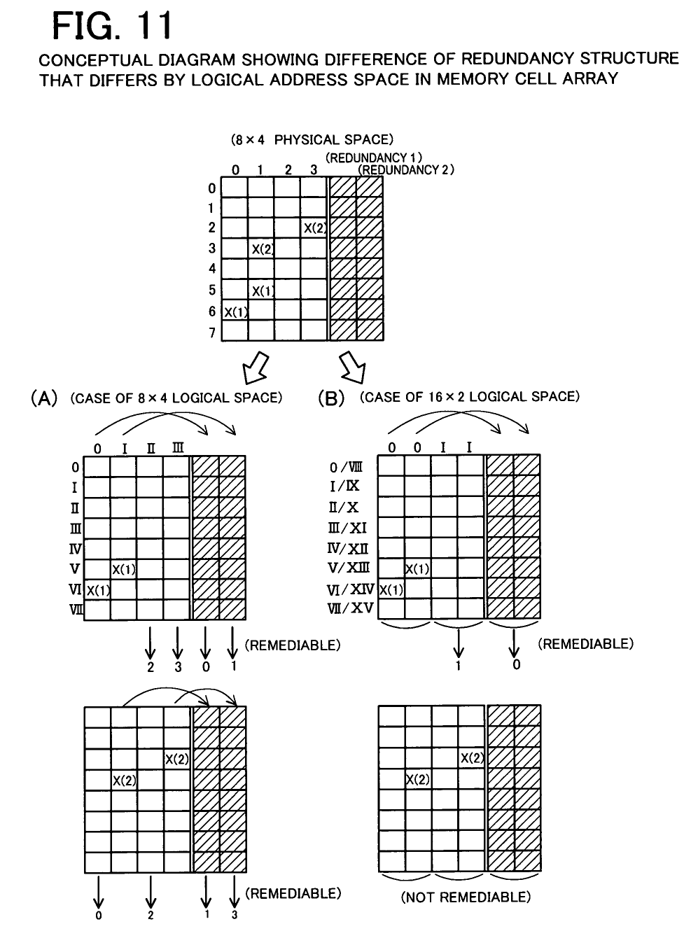

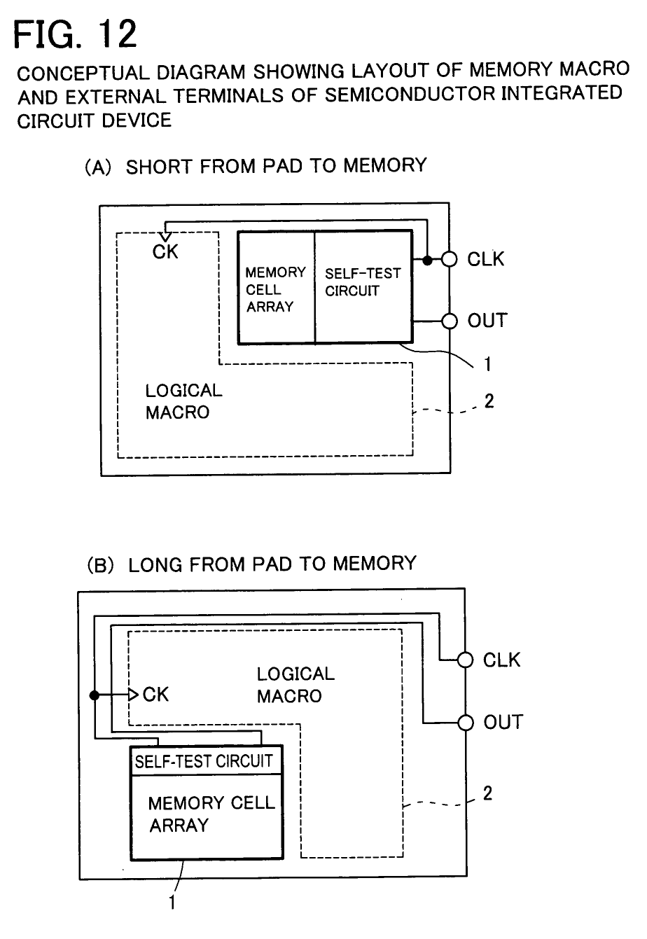

FIG. 9 is a circuit block diagram in the case a semiconductor integrated circuit device has two memory cell arrays A, B (11A, 11B), as a fourth embodiment. The memory cell arrays A, B (11A, 11B) are controlled by a logical macro 2A using control signals CTLA, CTLB and latency-value information L0A, L0B, and perform input/output of data DA, DB.

The optimum frequency and the optimum data latency that realize the optimum operation with the memory cell arrays A, B (11A, 11B) alone differ from control conditions from the logical macro 2A and may differ between the memory cell arrays. FIG. 9 shows an exemplary circuit structure in the case of performing a self-test on such memory cell arrays A, B (11A, 11B).

A self-test circuit 15D has a frequency controlling section 16B and a latency-value storing section 17B. To the frequency controlling section 16B, a clock signal CLK supplied from outside is inputted and a selecting signal A/B designating a memory cell array to be a test subject is also inputted. This is the setting for outputting an internal clock signal iCLKA or iCLKB corresponding to the optimum frequency in the selected memory cell array. The outputted internal clock signal iCLKA or iCLKB is inputted to a clock-supply switching section 28, and the internal clock signal iCLKA or iCLKB is supplied to the memory cell array 11A or 11B selected in accordance with the selecting signal A/B.

To the latency-value storing section 17B, optimum latency-value information for each memory cell array is stored and the selecting signal A/B designating a memory cell array to be a test subject is inputted. Latency-value information L1A or L1B is outputted to the selected memory cell array. The outputted latency-value information L1A or L1B is inputted to a latency-value-supply switching section 29, and the latency-value information L1A or L1B is supplied to the memory cell array 11A or 11B selected in accordance with the selecting signal A/B.

Although a set-latency-value switching section for performing switching between L1A or L1B, and the latency-value information L0A or L0B in normal operation is not shown, it can be installed on a stage preceding or following the latency-value-supply switching section 29.

In the description of the fourth embodiment, the selecting signal A/B is supplied from outside. However, this embodiment is not limited to this structure. The selecting signal A/B may also be supplied from the logical macro 2A or another control circuit, not shown. Alternatively, two or more memory arrays may be sequentially selected.

The present invention is not limited to the above-described embodiments and various improvements and modifications can be implemented without departing from the scope of the present invention.

For example, in the embodiment, the inner bus is set in the direction of physical columns, and redundancy remedy is performed after a self-test is performed on each physical column, whereas a self-test may be performed in the direction of physical rows and then redundancy remedy may be performed on each physical row. In this case, a row selection control signal is constructed to be provided with an inner row selecting signal for performing row selection control by physical row and an outer row selecting signal for performing row selection control by logical row instead of the inner/outer buses.

According to the present invention, it is possible to provide a semiconductor integrated circuit device having a memory macro that enables testing of an optimum test unit under optimum test conditions when testing the memory macro provided in the semiconductor integrated circuit device, irrespective of operation specifications set in the semiconductor integrated circuit device.

What is claimed is:

1. A semiconductor integrated circuit device provided with a memory macro for conducting access operation to a plurality of memory cells arranged in memory cell array under normal operation by selecting a logical row region and a logical column region that are in a basic region within a logical address space of the memory cell array, the semiconductor integrated circuit device comprising:
a defective region detecting section for detecting whether or not a defective memory cell exits by each physical row region or each physical column region based on physical layout of the memory cell array;
at least one unit of redundancy region for remedying a defective memory cell by each physical row region or each physical column region in accordance with a detection result obtained by the defective region detecting section;
an allocating section for allocating at least one unit of the physical row region or the physical column region to one unit of the logical row region or the logical column region, respectively.

2. A semiconductor integrated circuit device according to claim 1, wherein the physical row region or the physical column region is a minimum unit electrically controllable in view of physical layout of the memory cell array.

3. A semiconductor integrated circuit device according to claim 1, wherein
the physical row region is a plurality of the memory cells to be selected by at least one word line electrically and individually controllable out of a plurality of word lines physically arranged in the memory cell array, and
the physical column line is a plurality of the memory cells to be selected by at least one bit line electrically and individually controllable out of a plurality of bit lines physically arranged in the memory cell array.

4. A semiconductor integrated circuit device provided with a memory macro and a logical macro and operable along with a clock signal supplied from an external section, the semiconductor integrated circuit device comprising:
a self-test circuit for conducting a test of the memory macro, the self-test circuit being operable apart from the logical macro and; and
a frequency controlling section for converting the clock signal into an internal clock signal that is a maximum frequency of the memory macro when the test of the memory macro is conducted.

5. A semiconductor integrated circuit device according to claim 4, wherein the frequency controlling section converts the clock signal based on test condition information supplied from an external section.

6. A semiconductor integrated circuit device according to claim 5, wherein the test condition information relates to information on division/multiplication of the clock signal.

7. A semiconductor integrated circuit device according to claim 4, wherein the memory macro includes two or more of memory cell array maximum frequency of which differ from each other, and the frequency controlling section outputs the internal clock signal suitable to the memory cell array subject to the test.

8. A semiconductor integrated circuit device according to claim 7 further comprising a clock-supply switching section for supplying the internal clock signal to corresponding memory cell array.

9. A semiconductor integrated circuit device provided with a memory macro with self-test function for memory cell array, the semiconductor integrated circuit device comprising:
a data-latency controlling section for controlling latency of data inputted/outputted from the memory cell array;
a set-latency-value switching section for supplying a first-latency-value information to be set in normal operation and a second-latency-value information to be set in self-test; and
a latency-value storing section for storing the second-latency-value information.

10. A semiconductor integrated circuit device according to claim 9, wherein
the first-latency-value information is information of a latency value needed for operating the memory macro as a function circuit, and
the second-latency-value information is information of a latency value needed for operation by maximum frequency of the memory macro.

11. A semiconductor integrated circuit device according to claim 9, wherein the second-latency-value information is stored in the latency-value storing section based on test condition information supplied from an external section.

12. A semiconductor integrated circuit device according to claim 11, wherein the test condition information is information relating to the second-latency-value information.

13. A semiconductor integrated circuit device according to claim 9, wherein the memory macro includes two or more of memory cell array second-latency-value information of which differ from each other, and the latency-value storing section outputs the second-latency-value information suitable to the memory cell array subject to the test.

14. A semiconductor integrated circuit device according to claim 13 further comprising a latency-value-supply switching section for supplying the second-latency-value information stored in the latency-value storing section to corresponding memory cell array.

15. A semiconductor integrated circuit device provided with a memory macro with self-test function for memory cell array, the semiconductor integrated circuit device comprising:
a defective region storing section for storing a detection result indicating presence/absence of a defective memory cell for each of predetermined regions in the memory cell array; and
an output latency controlling section for controlling output latency of the detection result depending on propagation delay time to propagate from the defective region storing section through an output path and operation frequency of the clock signal when the detection result is outputted based on a clock signal supplied from an external section.

16. A semiconductor integrated circuit device according to claim 15, wherein, in the output latency controlling section, an output latency value is adjusted based on test condition information supplied from an external section.

17. A semiconductor integrated circuit device according to claim 16, wherein the test condition information relates to the output-latency-value information.

18. A self-test method of memory macro built in a semiconductor integrated circuit device that includes a memory macro for conducting access operation to a plurality of memory cells arranged in memory cell array under normal operation by selecting a logical row region and a logical column region that are in a basic region within a logical address space of the memory cell array, the self-test method comprising steps of:
test-unit extracting step where the logical row region or the logical column region is divided out to at least one unit of physical row region or physical column region, respectively, based on physical layout of the memory cell array; and
defective-region extracting step where absence/presence of a defective memory cell is detected for each physical row region or each physical column region.

19. A self-test method of memory macro built in a semiconductor integrated circuit device that includes a memory macro and a logical macro and is operable along with a clock signal supplied from an external section, the self-test method comprising steps of:
control stopping step where control of the memory macro by the logical macro is stopped based on a self-test-start command; and
test-clock supplying step where the clock signal is converted with reference to the memory macro so that an internal clock signal equivalent to operable frequency of the memory macro is supplied by a self-test-start command.

20. A self-test method of memory macro built in a semiconductor integrated circuit device provided with a memory macro for conducting data-input/data-output from memory cell array, the self-test method comprising steps of:
test-latency-value storing step where test-latency-value information with reference to data inputted/outputted from the memory cell array is stored when self test is conducted;
test-latency-value setting step where the test-latency-value information is set in accordance with a self-test-start command; and
a data-latency controlling step where latency of data inputted/outputted from the memory cell array is controlled in accordance with the test-latency-value information set in the test-latency value setting step.

21. A self-test method of memory macro built in a semiconductor integrated circuit device provided with a memory macro for conducting data-input/data-output from memory cell array, the self-test method comprising steps of:
defective-region storing step where a detection result of presence/absence of a defective memory cell is stored for each of predetermined regions within the memory cell array;
output-latency determining step where an output latency value of the detection result is determined based on propagation delay time until an output of the detection result and operation frequency of the clock signal when the detection result is to be outputted based on a clock signal supplied from an external section; and
defective-region outputting step where the detection result is outputted in form of the output latency value based on the clock signal.
